(19) United States
(12) Patent Application Publication
(10) Pub. No.: US 2026/0147281 A1
(43) Pub. Date: May 28, 2026

(54) PROCESS WINDOW QUALIFICATION FOR A PATTERNING PROCESS

(71) Applicant: Applied Materials Israel Ltd., Rehovot (IL)

(72) Inventors: Yorick TROUILLER, Grenoble (FR); Frederic ROBERT, Grenoble (FR); Michael SHIFRIN, Ashkelon (IL)

(21) Appl. No.: 18/961,313

(22) Filed: Nov. 26, 2024

(51) Int. Cl. G03F 7/00

(52) U.S. Cl. CPC G03F 7/70625; G03F 7/70441; G03F 7/706837; G03F 7/706839; G03F 7/706847

(57) ABSTRACT

There is provided a system and method of process window qualification. The method includes obtaining a wafer comprising a plurality of dies respectively printed under a plurality of process window conditions characterized by varying values of focus and exposure, wherein the wafer is fabricated in accordance with a chip design containing a pattern of interest (POI) comprising a surface structure and an underneath structure; inspecting the wafer at POI locations to obtain a plurality of images each capturing an occurrence of the POI; and providing a group of measurements from the plurality of images, comprising, for each given image: extracting a surface contour of the surface structure and an underneath contour of the underneath structure; shifting one of the contours relative to the other one or more times to simulate one or more overlay variations; and measuring a critical metric between the contours following each shift.

### TECHNICAL FIELD

The presently disclosed subject matter relates, in general, to the field of examination of a semiconductor specimen, and more specifically, to process window qualification for the semiconductor patterning process.

### BACKGROUND

Current demands for high density and performance associated with ultra large-scale integration of fabricated devices require submicron features, increased transistor and circuit speeds, and improved reliability. As semiconductor processes progress, pattern dimensions such as line width, and other types of critical dimensions, are continuously shrunken. Such demands require formation of device features with high precision and uniformity, which, in turn, necessitates careful monitoring of the fabrication process, including automated examination of the devices while they are still in the form of semiconductor wafers.

Process Window Qualification (PWQ) is a critical methodology in semiconductor manufacturing for evaluating the robustness and stability of fabrication processes. As semiconductor feature sizes continue to shrink and device complexity increases, it becomes essential to define and control the range of process conditions, characterized by critical parameters such as focus and exposure, that result in acceptable device performance. PWQ involves testing semiconductor wafers under various process conditions, capturing the range of parameters within which critical features can be reliably formed according to the design specifications. By examining these conditions and qualifying the process window, manufacturers can identify optimal parameter settings, minimize process variability, and enhance yield and reliability across the production line. This qualification is particularly important for advanced nodes, where even slight deviations in process conditions can lead to significant defects or performance issues in the final product.

### SUMMARY

In accordance with certain aspects of the presently disclosed subject matter, there is provided a computerized system of process window qualification, the system comprising a processing circuitry configured to obtain a wafer comprising a plurality of dies respectively printed under a plurality of process window conditions characterized by varying values of focus and exposure, wherein the wafer is fabricated in accordance with a chip design containing a pattern of interest (POI), resulting in one or more occurrences of the POI on each die, the POI comprising at least a surface structure and an underneath structure; inspect the wafer at locations corresponding to the occurrences of the POI on each die, to obtain a plurality of images each capturing an occurrence of the POI on the wafer; and provide a group of measurements pertaining to the POI from the plurality of images, comprising, for each given image: extract a surface contour of the surface structure and an underneath contour of the underneath structure; shift one of the surface contour and underneath contour relative to the other contour one or more times to simulate one or more overlay variations; and measure a critical metric between the surface contour and the underneath contour following each shift, giving rise to one or more measurements from the given image.

In addition to the above features, the system according to this aspect of the presently disclosed subject matter can comprise one or more of features (i) to (ix) listed below, in any desired combination or permutation which is technically possible:
(i). the processing circuitry can be further configured to: compare the group of measurements with a specification pertaining to the critical metric; and determine a margin and/or a center of a multi-dimensional process window characterized by focus, exposure, and overlay, based on a subset of measurements that meet the specification.
(ii). the margin and/or the center of the multi-dimensional process window can be usable to adapt one or more critical parameters of a lithography tool and/or an etching tool, or remanufacture a mask used by the lithography tool with improved Optical Proximity Correction (OPC) on problematic POIs.
(iii). the locations corresponding to the occurrences of the POI can be provided by Optical Proximity Correction (OPC) simulation.
(iv). the critical metric can represent one of: a minimal distance between the surface contour and the underneath contour, a minimal overlapped distance or area of the surface contour and the underneath contour, a minimal enclosure of distance or area of the surface contour and the underneath contour, and a distance from design to the surface contour and/or the underneath contour.
(v). the shifting is to simulate one or more overlay variations in X and/or Y directions.
(vi). the occurrences of the POI on each die can be associated with respective locations thereof within the die, and the group of measurements are provided with respect to the respective locations associated with the occurrences and compared with local specifications defined for the respective locations. The margin and/or the center can thus be determined as local parameters for the respective locations, enabling to derive local process windows respectively for the occurrences of the POI.
(vii). the surface structure is from a surface layer of the wafer which is printed under the plurality of process window conditions, while the underneath structure is from an underneath layer of the wafer which is printed under a fixed process window condition.
(viii). the wafer can be inspected using an e-beam tool to obtain the plurality of images, each image comprising a secondary electron (SE) image component from which the surface contour is extracted, and a back-scattered electron (BSE) image component from which the underneath contour is extracted.
(ix). the wafer can be further inspected using an optical inspection tool to assess defectivity for each die, wherein the assessed defectivity and the group of measurements are used in combination for qualifying the process window for the chip design.

In accordance with other aspects of the presently disclosed subject matter, there is provided a computerized method of process window qualification, the method comprising: obtaining a wafer comprising a plurality of dies respectively printed under a plurality of process window conditions characterized by varying values of focus and exposure, wherein the wafer is fabricated in accordance with a chip design containing a pattern of interest (POI), resulting in one or more occurrences of the POI on each die, the POI comprising at least a surface structure and an underneath structure; inspecting the wafer at locations corresponding to the occurrences of the POI on each die, to obtain a plurality of images each capturing an occurrence of the POI on the wafer; and providing a group of measurements pertaining to the POI from the plurality of images, comprising, for each given image: extracting a surface contour of the surface structure and an underneath contour of the underneath structure; shifting one of the surface contour and underneath contour relative to the other contour one or more times to simulate one or more overlay variations; and measuring a critical metric between the surface contour and the underneath contour following each shift, giving rise to one or more measurements from the given image.

These aspects of the disclosed subject matter can comprise one or more of features (i) to (ix) listed above with respect to the system, mutatis mutandis, in any desired combination or permutation which is technically possible.

In accordance with other aspects of the presently disclosed subject matter, there is provided a non-transitory computer readable medium comprising instructions that, when executed by a computer, cause the computer to perform a method of process window qualification, the method comprising: obtaining a wafer comprising a plurality of dies respectively printed under a plurality of process window conditions characterized by varying values of focus and exposure, wherein the wafer is fabricated in accordance with a chip design containing a pattern of interest (POI), resulting in one or more occurrences of the POI on each die, the POI comprising at least a surface structure and an underneath structure; inspecting the wafer at locations corresponding to the occurrences of the POI on each die, to obtain a plurality of images each capturing an occurrence of the POI on the wafer; and providing a group of measurements pertaining to the POI from the plurality of images, comprising, for each given image: extracting a surface contour of the surface structure and an underneath contour of the underneath structure; shifting one of the surface contour and underneath contour relative to the other contour one or more times to simulate one or more overlay variations; and measuring a critical metric between the surface contour and the underneath contour following each shift, giving rise to one or more measurements from the given image.

This aspect of the disclosed subject matter can comprise one or more of features (i) to (xi) listed above with respect to the system, mutatis mutandis, in any desired combination or permutation which is technically possible.

### BRIEF DESCRIPTION OF THE DRAWINGS

In order to understand the disclosure and to see how it may be carried out in practice, embodiments will now be described, by way of non-limiting example only, with reference to the accompanying drawings, in which:

FIG. 1 illustrates a generalized block diagram of an examination system in accordance with certain embodiments of the presently disclosed subject matter.

FIG. 2 illustrates a generalized flowchart of process window qualification in accordance with certain embodiments of the presently disclosed subject matter.

FIG. 3 illustrates a generalized flowchart detailing step 204 of the inspection process in accordance with certain embodiments of the presently disclosed subject matter.

FIG. 4 illustrates a generalized flowchart of using the group of measurements for process window qualification in accordance with certain embodiments of the presently disclosed subject matter.

FIG. 5 shows a schematic illustration of an example of a FEM wafer in accordance with certain embodiments of the presently disclosed subject matter.

FIG. 6 illustrates a specific example of a Pattern of Interest (POI) and its behavior under variations in exposure, focus, and overlay, in accordance with certain embodiments of the present invention.

### DETAILED DESCRIPTION OF EMBODIMENTS

The process of semiconductor manufacturing often requires multiple sequential processing steps and/or layers, some of which could possibly cause errors that may lead to yield loss. Examples of various processing steps can include lithography, etching, depositing, planarization, growth (such as, e.g., epitaxial growth), and implantation, etc. Various examination operations, such as defect-related examination (e.g., defect detection, defect review, and defect classification, etc.), and/or metrology-related examination (e.g., critical dimension (CD) measurements, etc.), can be performed at different processing steps/layers during the manufacturing process to monitor and control the process. The examination operations can be performed a multiplicity of times, for example after certain processing steps, and/or after the manufacturing of certain layers, or the like.

In semiconductor manufacturing, Process Window Qualification (PWQ) is a vital process for validating the feasibility of producing a specific chip design. It involves fabricating a specific specimen to assess whether the design can be reliably produced and to determine the range of process conditions within which the specific chip design can be reliably produced without introducing critical defects.

PWQ is a fab procedure to qualify processing steps in the patterning process, which typically includes the lithography process (i.e., a photomasking process where light is projected through a patterned mask onto a photosensitive layer applied on the wafer (e.g., photoresist) to transfer the mask's design onto the photoresist), and the etching process (which selectively removes material from specific areas on the wafer based on the exposed pattern, where areas unprotected by the photoresist are etched away to transfer the lithographically patterned design onto the underlying wafer layers).

PWQ can help identify various defect types on the wafer post-patterning, including design-related defects, reticle-related defects, and process-induced defects. These defects can often be systematic in nature and may recur at specific locations in the design where features are particularly sensitive to process variability. Such defect-prone regions are known as hotspots.

Hotspots typically arise in regions where the design's geometrical complexity interacts unfavorably with process variations, often due to insufficient compensations for the limitations of the lithography process. For example, a hotspot might occur where a feature's dimensions push the boundaries of the process's resolution limits, making it more vulnerable to focus or exposure deviations. These vulnerabilities are often mitigated through Optical Proximity Correction (OPC), a technique used to modify mask patterns to account for distortions caused by the lithography process. OPC compensates for issues such as light diffraction and proximity effects, which can cause printed features to differ from the intended design, particularly in submicron geometries. By adjusting the mask shapes, OPC helps ensure that the printed features on the wafer more accurately match the intended design specifications.

In addition, OPC also serves as a valuable predictive tool used in simulation to identify potential hotspots-specific locations in the design that are likely to experience defects due to process variations. OPC simulation predicts areas where the design's inherent geometrical complexities may result in a higher likelihood of defects if there is any shift in critical parameters, such as focus or exposure. By simulating the lithography process on a detailed level, OPC identifies these hotspots, where features are at greater risk of distortion, bridging, or other issues under real-world process conditions. These hotspots then serve as input locations for Process Window Qualification (PWQ), focusing PWQ on the areas of the design that are most vulnerable to process variations.

PWQ is typically performed on a focus-exposure modulated specimen (e.g., a wafer) which is used to simulate various process window conditions, characterized by differences in focus and exposure. Traditionally, a defect-based PWQ approach uses optical inspection tools to identify defects at the hotspots. These defects are then reviewed and classified (e.g., by SEM review) to assess how patterns respond to variations in focus and exposure, enabling the determination of a workable process window.

However, this conventional approach has notable limitations. Optical inspection primarily provides binary information, categorizing areas as “defective” or “non-defective” based on the presence of visible defects such as, e.g., pattern collapse or bridging, etc. This binary assessment does not account for deviations in feature dimensions (e.g., critical dimension (CD) variation) that, while within binary “non-defective” thresholds, may still fall outside of specification limits. Consequently, recent advancements have incorporated metrology tools to assess dimensional impacts due to focus and exposure variations, providing more granular data. By measuring the CD of critical hotspots, metrology tools help refine the process window by highlighting instances where patterns, though acceptable under optical inspection, may deviate dimensionally and thus fall outside acceptable process limits. This approach ensures a more precise understanding of the process window's boundaries.

Despite these advancements, current PWQ methods are still limited by their primary focus on variations in focus and exposure, without accounting for additional critical components, such as, e.g., overlay variations. Overlay generally refers to misalignments between different pattern layers. Overlay accuracy is another critical parameter for patterning tools, as misalignment between layers can significantly impact device functionality. However, integrating overlay into the process window assessment alongside focus and exposure presents significant challenges, as it introduces at least an additional dimension (with potential variations in both x and y directions). Expanding the qualification to simultaneously test focus, exposure, and overlay would require an impractically high number of wafers, making the process infeasible in terms of wafer preparation, metrology, and inspection time.

To address these limitations, certain embodiments of the presently disclosed subject matter propose a hybrid approach to Process Window Qualification (PWQ) that enables comprehensive assessment across focus, exposure, and overlay variations using a single wafer. This is achieved by leveraging a virtual methodology for overlay variation, rather than conducting multiple physical experiments. In this approach, a modulated wafer is initially fabricated under varying focus and exposure conditions. However, instead of producing additional wafers for overlay testing, the present subject matter proposes to virtually shift the contour of one layer relative to the other, simulating overlay variations within known tolerance ranges of the lithography tool. This virtual shifting enables measurement of critical dimensions post-shift, revealing whether the design remains within specification despite potential overlay misalignments, as will be detailed below.

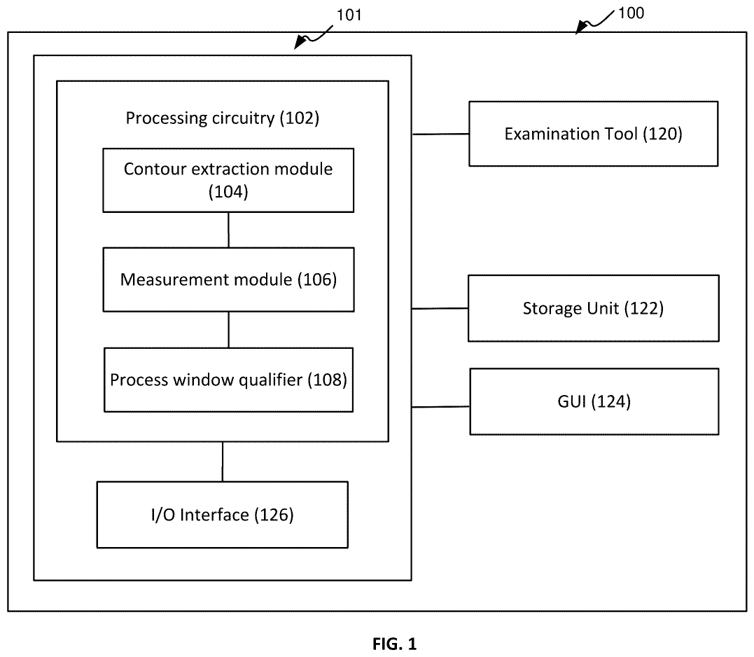

Bearing this in mind, attention is drawn to FIG. 1 illustrating a functional block diagram of an examination system in accordance with certain embodiments of the presently disclosed subject matter.

The examination system 100 illustrated in FIG. 1 can be used for examination of a semiconductor specimen as part of the specimen fabrication process. As described above, the examination referred to herein can be construed to cover any kind of operations related to defect inspection/detection, defect review, defect classification, nuisance filtration, segmentation, and/or metrology operations, etc., with respect to the specimen.

As mentioned above, the semiconductor specimen used in the present disclosure is a specifically engineered, modulated wafer designed for Process Window Qualification (PWQ). This wafer comprises a plurality of dies, each fabricated under distinct process conditions that vary systematically in terms of focus and exposure. These variations are purposefully introduced according to a focus-exposure matrix to simulate a range of real-world process window conditions that a production wafer might encounter.

The focus-exposure matrix across the wafer can be organized to include multiple process points, typically arranged in a grid or matrix pattern, representing incremental changes in focus and exposure. For instance, focus values may be adjusted in steps (e.g., from −50 nm to +50 nm), while exposure levels may be similarly varied (e.g., from a low exposure dose to a high exposure dose). This methodical variation allows for the creation of process windows around each critical design feature, giving insights into how far each parameter can deviate before defects or unacceptable dimensional shifts occur.

By creating dies under these diverse settings, the modulated wafer captures a broad spectrum of process-induced variability, enabling an in-depth analysis of how different process parameters affect the critical design features.

The dies on the wafer are patterned according to a specific chip design, ensuring that the design elements and structures are consistently replicated across dies despite the intentional variability in processing conditions. The chip design includes critical features/patterns known to be sensitive to process variations, thus prone to defects, referred to as hotspots. These hotspots might include areas where pattern collapse, bridging, or other structural weaknesses are more likely, making the modulated wafer highly relevant for verifying the design's resilience under varying focus and exposure settings across the process window.

In some embodiments of the present disclosure, one of such hotspots in the chip design is referred to as a pattern of interest (POI). When patterning the wafer according to the chip design, it results in one or more occurrences of the POI on each die. Specifically, the POI may comprise at least a surface structure from a surface layer (also referred to as a top structure from a top layer) and an underneath structure from an underneath layer (also referred to as a bottom structure from a bottom layer).

System 100 comprises one or more examination tools 120 configured to scan the specifically modulated specimen and capture images thereof to be further processed for various examination applications.

The term “examination tool(s)” used herein should be expansively construed to cover any tools that can be used in examination-related processes, including, by way of non-limiting example, scanning (in a single or in multiple scans), imaging, sampling, reviewing, measuring, classifying, and/or other processes provided with regard to the specimen or parts thereof. Without limiting the scope of the disclosure in any way, it should also be noted that the examination tools can be implemented as inspection machines of various types, such as optical inspection machines, electron beam inspection machines (e.g., a Scanning Electron Microscope (SEM), an Atomic Force Microscopy (AFM), or a Transmission Electron Microscope (TEM), etc.), and so on.

In some embodiments of the present disclosure, at least one of the examination tools 120 has metrology capabilities and can be configured to capture images and perform metrology operations on the captured images. Such an examination tool is also referred to as a metrology tool.

One example of a metrology tool used within the examination system is a Critical Dimension Scanning Electron Microscope (CD-SEM). CD-SEM is a specialized tool designed to capture high-resolution images of semiconductor structures and perform precise dimensional measurements on those structures, typically at the nanoscale. In the present disclosure, the CD-SEM captures detailed images of critical features/patterns on the modulated wafer, enabling accurate measurements of the features' dimensions under varying process window conditions. The CD-SEM can be used to obtain critical dimension (CD) measurements with respect to certain structural features on the specimen, to determine if they meet the design specifications across different focus and exposure settings. Additionally, the CD-SEM's metrology capabilities can be leveraged to measure critical metrics between layers, such as critical distances, to assess whether these dimensions remain within acceptable limits.

In some embodiments, optionally, in addition to or in lieu of the metrology tool, the one or more examination tools 120 can include one or more inspection tools and/or one or more review tools. In some cases, an inspection tool can be configured to scan the specimen to capture inspection images (typically, at a relatively high-speed and/or low-resolution) for detection of potential defects (i.e., defect candidates). During inspection, the wafer can move at a step size relative to the detector of the inspection tool (or the wafer and the tool can move in opposite directions relative to each other) during the exposure, and the wafer can be scanned step-by-step along swaths of the wafer by the inspection tool, where the inspection tool images a part/portion (within a swath) of the specimen at a time. By way of example, the inspection tool can be an optical inspection tool. At each step, light can be detected from a rectangular portion of the wafer and such detected light is converted into multiple intensity values at multiple points in the portion, thereby forming an image corresponding to the part/portion of the wafer. For instance, in optical inspection, an array of parallel laser beams can scan the surface of a wafer along the swaths. The swaths are laid down in parallel rows/columns contiguous to one another, to build up, swath-at-a-time, an image of the surface of the wafer. For instance, the tool can scan a wafer along a swath from up to down, then switch to the next swath and scan it from down to up, and so on and so forth, until the entire wafer is scanned and inspection images of the wafer are collected.

In some cases, a review tool can be configured to capture review images of at least some of the defect candidates detected by inspection tools for ascertaining whether a defect candidate is indeed a defect of interest (DOI). Such a review tool is usually configured to inspect fragments of the specimen, one at a time (typically, at a relatively low-speed and/or high-resolution). By way of example, the review tool can be an electron beam tool, such as, e.g., a scanning electron microscope (SEM), etc.

The various examination tools can be different tools located at the same or at different locations, or integrated as a single tool operated in different modes. In some cases, the same examination tool can provide low-resolution image data and high-resolution image data. The resulting image data (low-resolution image data and/or high-resolution image data) can be transmitted - directly or via one or more intermediate systems - to system 101. The present disclosure is not limited to any specific type of examination tools and/or the resolution of image data resulting from the examination tools.

According to certain embodiments of the presently disclosed subject matter, the examination system 100 comprises a computer-based system 101 operatively connected to the examination tool 120, and capable of process window qualification across focus, exposure, and overlay variations using a single wafer. System 101 is also referred to as a PWQ system.

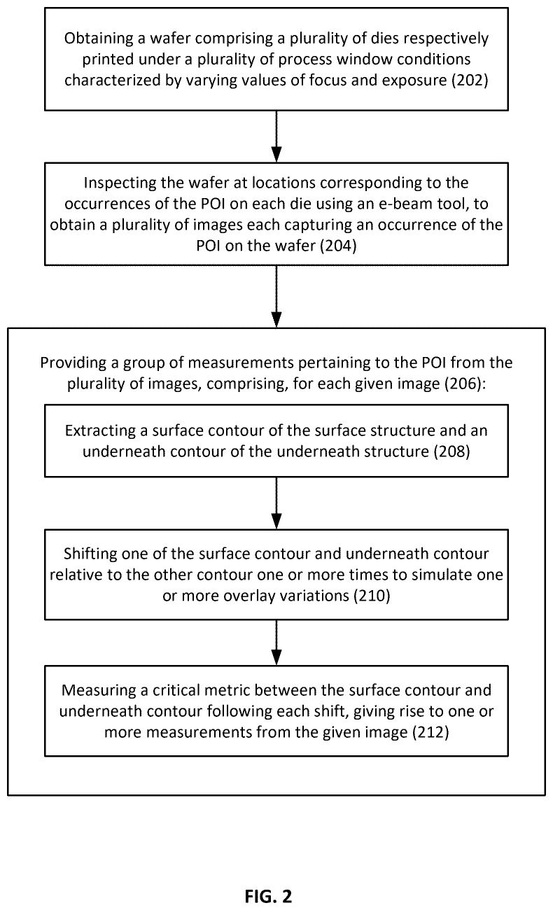

System 101 includes a processing circuitry 102 operatively connected to a hardware-based I/O interface 126 and configured to provide processing necessary for operating the system, as further detailed with reference to FIGS. 2-4. The processing circuitry 102 can comprise one or more processors (not shown separately) and one or more memories (not shown separately). The one or more processors of the processing circuitry 102 can be configured to, either separately or in any appropriate combination, execute several functional modules in accordance with computer-readable instructions implemented on a non-transitory computer-readable memory comprised in the processing circuitry. Such functional modules are referred to hereinafter as comprised in the processing circuitry.

According to certain embodiments, one or more functional modules comprised in the processing circuitry 102 of system 101 can include a contour extraction module 104, a measurement module 106, and a process window qualifier (PWQ) 108 operatively connected to each other.

Specifically, upon obtaining the specifically modulated wafer as described above, the examination tool 120 (such as, e.g., an e-beam tool) can be configured to inspect the wafer at locations corresponding to the occurrences of the POI on each die, to obtain a plurality of images, each capturing an occurrence of the POI on the wafer. For each given image, the contour extraction module 104 can be configured to extract a surface contour of the surface structure and an underneath contour of the underneath structure. The measurement module 106 can be configured to shift one of the surface contour and underneath contour relative to the other contour one or more times to simulate one or more overlay variations, and measure a critical metric between the surface contour and the underneath contour following each shift, giving rise to one or more measurements from the given image. Once the measurement is obtained for each given image of the plurality of images, a group of measurements pertaining to the POI can be provided corresponding to the plurality of images.

In some cases, the PWQ 108 can be configured to compare the group of measurements with a specification pertaining to the critical metric, and determine a margin and/or a center of a multi-dimensional process window characterized by focus, exposure, and overlay, based on a subset of measurements that meet the specification.

It is to be noted that while certain embodiments of the present disclosure refer to the processing circuitry 102 being configured to perform the above recited operations, the functionalities/operations of the aforementioned functional modules can be performed by the one or more processors in processing circuitry 102 in various ways. By way of example, the operations of each functional module can be performed by a specific processor, or by a combination of processors. The operations of the various functional modules, such as the contour extraction, contour shifting, critical metric measurement, and critical parameter determination, etc., can thus be performed by respective processors (or processor combinations) in the processing circuitry 102, while, optionally, these operations may be performed by the same processor. The present disclosure should not be limited to being construed as one single processor always performing all the operations.

In some cases, additionally to system 101, the examination system 100 can comprise one or more examination modules, such as, e.g., defect detection module, nuisance filtration module, Automatic Defect Review Module (ADR), Automatic Defect Classification Module (ADC), metrology operation module, and/or other examination modules which are usable for examination of the specimen. The one or more examination modules can be implemented as stand-alone computers, or their functionalities (or at least part thereof) can be integrated with the examination tools 120. In some cases, the output of system 101, e.g., the group of measurements, and/or the margin and center of the process window, can be provided to the one or more examination modules for further processing.

According to certain embodiments, system 100 can comprise a storage unit 122. The storage unit 122 can be configured to store any data necessary for operating system 101, e.g., data related to input and output of system 101, as well as intermediate processing results generated by system 101. By way of example, the storage unit 122 can be configured to store the plurality of images and/or derivatives thereof produced by the examination tool 120. Accordingly, the input data can be retrieved from the storage unit 122 and provided to the processing circuitry 102 for further processing. The output of the system 101, such as, e.g., the group of measurements, and/or the margin and center of the process window, can be sent to storage unit 122 to be stored.

In some embodiments, system 100 can optionally comprise a computer-based Graphical User Interface (GUI) 124 which is configured to enable user-specified inputs related to system 101. For instance, the user can be presented with a visual representation of the specimen (for example, by a display forming part of GUI 124). The user may be provided, through the GUI, with options of defining certain operation parameters, such as, e.g., the overlay variations, and the number of times of contour shifting, etc. The user may also view the operation results or intermediate processing results, such as, e.g., the margin and center of the process window, etc., on the GUI.

In some cases, system 101 can be further configured to send, via I/O interface 126, the operation results to the examination tools 120 for further processing. In some cases, system 101 can be further configured to send the results to the storage unit 122, and/or external systems (e.g., Yield Management System (YMS) of a fabrication plant (fab)). A yield management system (YMS) in the context of semiconductor manufacturing is a data management, analysis, and tool system that collects data from the fab, especially during manufacturing ramp-ups, and helps engineers find ways to improve yield. YMS helps semiconductor manufacturers and fabs manage high volumes of production analysis with fewer engineers. These systems analyze the yield data and generate reports. YMS can be used by Integrated Device Manufacturers (IMD), fabs, fabless semiconductor companies, and Outsourced Semiconductor Assembly and Test (OSAT).

Those versed in the art will readily appreciate that the teachings of the presently disclosed subject matter are not bound by the system illustrated in FIG. 1. Each system component and module in FIG. 1 can be made up of any combination of software, hardware, and/or firmware, as relevant, executed on a suitable device or devices, which perform the functions as defined and explained herein. Equivalent and/or modified functionality, as described with respect to each system component and module, can be consolidated or divided in another manner. Thus, in some embodiments of the presently disclosed subject matter, the system may include fewer, more, modified and/or different components, modules, and functions than those shown in FIG. 1.

Each component in FIG. 1 may represent a plurality of the particular components, which are adapted to independently and/or cooperatively operate to process various data and electrical inputs, and for enabling operations related to a computerized examination system. In some cases, multiple instances of a component may be utilized for reasons of performance, redundancy, and/or availability. Similarly, in some cases, multiple instances of a component may be utilized for reasons of functionality or application. For example, different portions of the particular functionality may be placed in different instances of the component.

It should be noted that the examination system illustrated in FIG. 1 can be implemented in a distributed computing environment, in which one or more of the aforementioned components and functional modules shown in FIG. 1 can be distributed over several local and/or remote devices. By way of example, the examination tools 120 and the system 101 can be located at the same entity (in some cases hosted by the same device) or distributed over different entities, depending on specific system configurations and implementation needs.

In some examples, certain components utilize a cloud implementation, e.g., are implemented in a private or public cloud. Communication between the various components of the examination system, in cases where they are not located entirely in one location or in one physical entity, can be realized by any signaling system or communication components, modules, protocols, software languages, and drive signals, and can be wired and/or wireless, as appropriate.

It should be further noted that in some embodiments at least some of examination tools 120, storage unit 122 and/or GUI 124 can be external to the examination system 100 and operate in data communication with systems 100 and 101 via I/O interface 126. System 101 can be implemented as stand-alone computer(s) to be used in conjunction with the examination tools, and/or with the additional examination modules as described above. Alternatively, the respective functions of the system 101 can, at least partly, be integrated with one or more examination tools 120, thereby facilitating and enhancing the functionalities of the examination tools in examination-related processes.

While not necessarily so, the process of operations of systems 101 and 100 can correspond to some or all of the stages of the methods described with respect to FIGS. 2-4. Likewise, the methods described with respect to FIGS. 2-4 and their possible implementations can be implemented by systems 101 and 100. It is therefore noted that embodiments discussed in relation to the methods described with respect to FIGS. 2-4 can also be implemented, mutatis mutandis as various embodiments of the systems 101 and 100, and vice versa.

Referring to FIG. 2, there is illustrated a generalized flowchart of process window qualification (PWQ) in accordance with certain embodiments of the presently disclosed subject matter.

As described above, a semiconductor specimen is typically made of multiple layers. The examination process of a specimen can be performed a multiplicity of times during the fabrication process of the specimen, for example following certain processing steps of specific layers. For the purpose of illustration only, certain embodiments of the following description are described with respect to PWQ for a given processing step/layer of the specimen. Those skilled in the art will readily appreciate that the teachings of the presently disclosed subject matter can be performed for any layer and/or processing steps of the specimen. The present disclosure should not be limited to the number of processing steps/layers comprised in the specimen and/or the specific layer(s) to be examined.

As described above, a specifically modulated specimen is needed for the purpose of performing the PWQ process. In some cases, such a specific specimen can be referred to as a Focus-Exposure Matrix (FEM) wafer, which is a specially fabricated test wafer (e.g., by a semiconductor manufacturer) designed to explore the impact of different focus and exposure settings on the printed patterns of a chip design.

The FEM wafer comprises a grid or matrix of dies, each exposed under a distinct combination of focus and exposure parameters, allowing for systematic evaluation of how these variations affect the critical dimensions and structural integrity of the design. By examining the printed features across a range of focus-exposure conditions, the FEM wafer helps define the process window, identifying the optimal settings and the tolerances within which the design can reliably be produced without defects or unacceptable dimensional deviations. In some cases, a Process Window Qualification (PWQ) wafer can be regarded as a specialized type of FEM wafer.

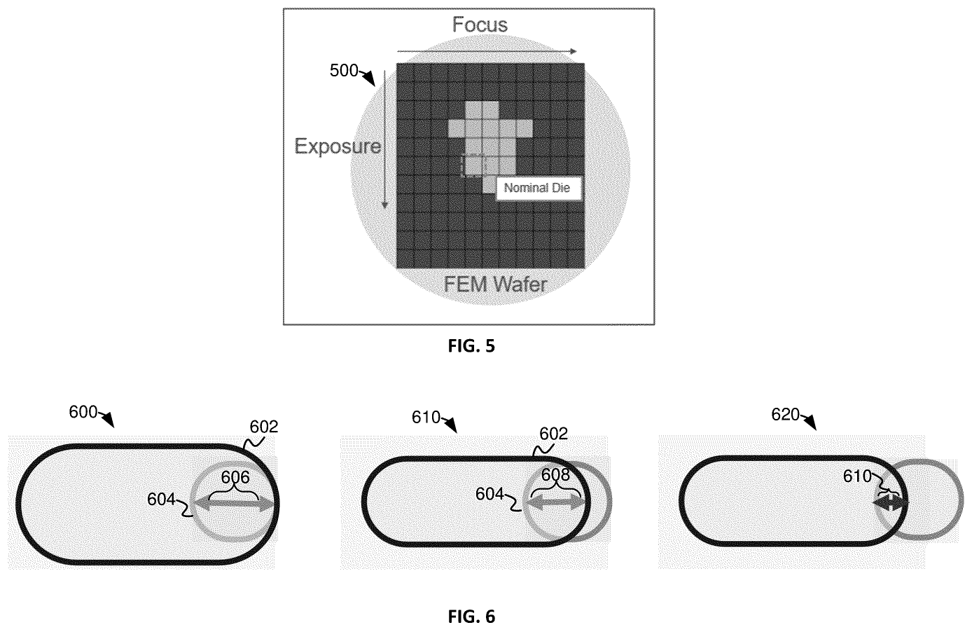

FIG. 5 shows a schematic illustration of an example of a FEM wafer in accordance with certain embodiments of the presently disclosed subject matter.

As shown, the FEM wafer is illustrated as a grid/matrix of dies organized along two primary axes: focus (represented on the x-axis) and exposure (represented on the y-axis). Each die within this matrix corresponds to a unique combination of focus and exposure settings, with incremental changes applied across the wafer to capture a range of process window conditions.

The x-axis represents variations in focus, where each position along this axis denotes a different focus setting applied during the lithography process. Moving along the x-axis, from left to right, reflects incremental adjustments to focus, capturing both under-focus and over-focus conditions relative to the center.

Similarly, the y-axis represents variations in exposure, with each position indicating a distinct exposure dose applied to that die. Moving up or down along the y-axis reflects adjustments in exposure dose, simulating conditions of under-exposure and over-exposure compared to the nominal exposure.

At the center of this matrix, a subset of dies is highlighted and labeled as nominal dies. After examination and measurement, these nominal dies are identified as having met the specification requirements, indicating that the features printed within these dies conform to the design tolerance criteria set for the process. These dies thus represent process conditions of the acceptable focus and exposure settings.

The objective of the PWQ process, as illustrated by FIG. 5, is typically to identify these nominal dies and determine the critical parameters of the process window defined by them. This involves characterizing the range of focus and exposure conditions that yield acceptable results, ensuring that the process remains robust within this defined window.

For clarity, it is to be noted that the x and y axes illustrated in FIG. 5 are for exemplary purposes only, and do not represent actual numerical values or units. The starting point of the x and y axes is positioned at the left corner of the wafer purely for illustrative purposes, and may not reflect actual coordinate systems or values used in manufacturing.

While traditional FEM wafers, as shown in FIG. 5, are typically used to assess process windows defined by focus and exposure alone, the present disclosure extends the analysis to include an additional, critical parameter: overlay. By leveraging the same single wafer, modulated by focus and exposure conditions, the present disclosure proposes a method that eliminates the need for multiple wafers or complex physical experiments for overlay, instead virtually incorporating overlay variation, enabling a more comprehensive qualification of the process window that now includes focus, exposure, and overlay, as will be described in detail below.

As mentioned above, the FEM wafer is manufactured in accordance with a chip design which typically comprises hotspots. A Pattern of Interest (POI), as defined above, represents one such hotspot within the chip design, i.e., an area known to be particularly sensitive to process variations. When the FEM wafer is patterned in alignment with this design, each die on the wafer contains one or more occurrences of the POI, thereby replicating these hotspots across the wafer under different combinations of focus and exposure conditions. This ensures that variations in process parameters can be systematically evaluated at these critical locations, providing insights into how these hotspots behave under various manufacturing conditions.

Specifically, in the present disclosure, the POI comprises at least a surface structure from a surface layer and an underneath structure from an underneath layer.

After the FEM wafer is obtained (202), it undergoes inspection (204), which can be performed using an examination tool such as an e-beam tool (e.g., the examination tool 120). This tool is capable of capturing detailed, high-resolution images of the POI at specific locations on each die. By focusing on these occurrences of the POI, the inspection yields a plurality of images, each capturing an instance of the POI occurrence on the wafer, including both the surface structure from the surface layer and the underneath structure from the underlying layer.

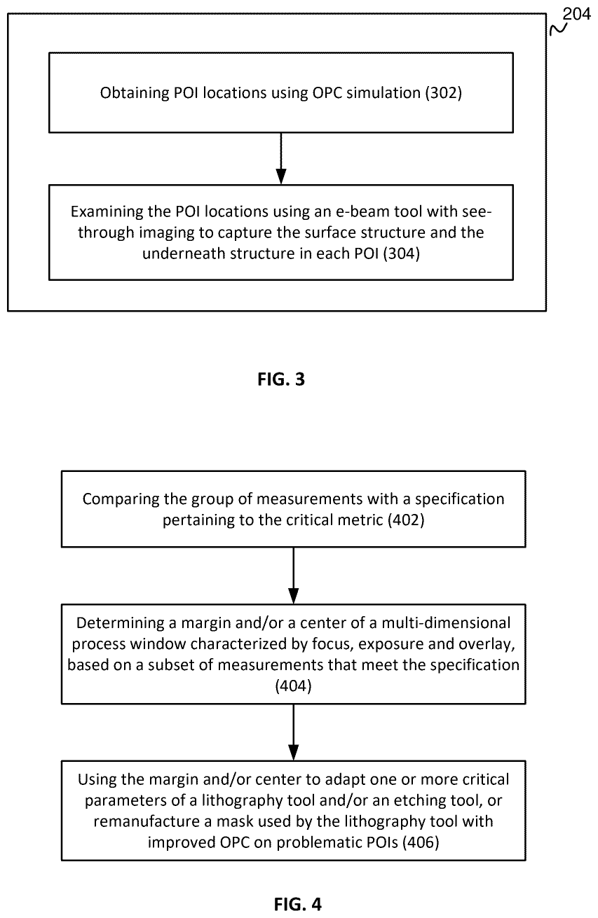

FIG. 3 illustrates a generalized flowchart detailing step 204 of the inspection process in accordance with certain embodiments of the presently disclosed subject matter.

To accurately target these critical areas, locations of the POI occurrences can be first obtained (302) through OPC simulation. The OPC simulation can analyze the chip design to identify hotspots which are specific design features that are prone to defects or dimensional deviations under variable process conditions (e.g., the POI being one of such hotspots). By mapping out these locations in advance, the inspection process can focus on these target areas, ensuring that the image data collected is relevant to evaluating the POI's robustness within the process window.

In particular, in some embodiments, the POI can be chosen as those design features that are most sensitive to overlay variations. By way of example, the OPC can provide full chip simulation including information regarding sensitivity to overlay variations, based on which POIs with relatively higher sensitivity can be selected. Selecting POIs with higher sensitivity to overlay can be beneficial because these areas are often the most challenging to align accurately across multiple layers, making them critical indicators of process robustness. By focusing the inspection on these overlay-sensitive POIs, the acquired image data can more effectively highlight potential misalignment issues and dimensional deviations that may arise from even slight overlay shifts, thus enhancing the precision of the process window qualification.

Once these locations are identified, the e-beam tool can be used to examine (304) each POI location, leveraging see-through imaging capabilities to capture both the surface structure and the underneath structure in each POI. The see-through imaging approach utilizes secondary electrons (SE) and backscattered electrons (BSE), allowing for layer-specific imaging of the surface and underlying structures, respectively.

Specifically, SE imaging is used to capture the surface layer of the POI. When the e-beam tool scans the wafer, secondary electrons are emitted from the surface, providing high-resolution information on the topography and fine features of the surface structure, resulting in a SE image of the surface structure. BSE imaging is utilized to capture the underneath layer of the POI. Backscattered electrons, which originate deeper within the specimen and are deflected back to the detector, provide information on underlying structures that may not be visible in SE imaging. This approach effectively “sees through” the surface layer to capture the shape and position of features in the underneath structure, resulting in a BSE image of the underneath structure, and enabling analyzing overlay alignment between the two layers.

To clarify, when it was described above that the inspection yields a plurality of images, each capturing an instance of the POI occurrence on the wafer, it should be understood that with the see-through imaging, each image of the plurality of images actually comprises two image components: an SE image component which captures the surface structure of the POI, and a BSE image component which captures the underneath structure. Together, the SE and BSE image components provide a comprehensive view of both the surface and underneath structures within each POI.

Following the acquisition of the plurality of images, the next step involves analyzing these images to provide (206) a group of measurements pertaining to the Pattern of Interest (POI) from these images. Each image will undergo a series of processing steps as detailed below to extract specific measurements that reflect how the POI features behave under the applied process variations.

Specifically, for each given image within the plurality of images, a surface contour of the surface structure and an underneath contour of the underneath structure can be extracted (208) (e.g., by the contour extraction module 104) from the given image. The contour extraction can be performed using various contour extraction or image segmentation techniques. By way of example, in some cases, edge-detection algorithms (e.g., Canny, Sobel) may be employed to detect the boundaries of the surface and underneath structures within the SE and BSE images, respectively. In some other cases, machine learning (ML)-based segmentation can be utilized, where ML models trained on annotated POI images can accurately segment the contours of both layers. Alternatively, in some cases, region-based segmentation (e.g., clustering methods) could be implemented to separate the layers, based on pixel intensity differences or texture patterns.

It is to be noted that the above examples are provided for exemplary purposes only, and the contour extraction used herein is not limited to any specific method, allowing it to possibly adapt, based on the specific imaging requirements and system configurations.

Once the contours of the surface and underneath structures are extracted, one of these contours can be virtually shifted (210) relative to the other contour one or more times to simulate one or more overlay variations. Such virtual shifting is essential to the present subject matter, as it enables overlay qualification without requiring multiple physical wafers with actual physical overlay variations.

In some embodiments, the surface contour can be shifted relative to the underneath contour. By shifting only the surface layer contour, the system can simulate a range of potential overlay misalignments without disturbing the reference underneath layer, representing a realistic scenario where the underneath layer acts as a stable foundation for testing surface layer alignment. In some other embodiments, the underneath contour can be shifted relative to the surface contour. This approach can be particularly advantageous because the bottom layer is considered a fixed reference, meaning it has already been manufactured under stable, uniform conditions, and remains unaffected by subsequent process variations. Consequently, no changes or variations occur in the features or contours of this bottom layer, allowing it to serve as a consistent, reliable baseline for overlay testing. Shifting the underneath contour virtually, therefore, provides a simpler and more controlled means of simulating overlay variations.

The shifting process can include overlay variations in X and/or Y directions and can represent incremental or specific overlay displacements based on expected overlay tolerances in an overlay process window of the lithography process. Each shift corresponds to a unique alignment scenario, simulating the potential misalignments that might occur in a production environment. This virtual shifting provides a practical and efficient means of assessing whether the alignment of the layers within the POI remains within acceptable limits under various overlay scenarios, without requiring additional physical specimens for each overlay condition.

In some cases, the shifting can be performed in accordance with overlay variations solely in the X direction. For instance, the underneath contour can be shifted horizontally relative to the surface contour to represent alignment deviations along the X-axis. In some other cases, shifting can be performed in accordance with overlay variations solely in the Y direction. For instance, the underneath contour can be shifted vertically to simulate misalignments along the Y-axis. Additionally, in some further embodiments, the shifting can be performed in accordance with overlay variations in both X and Y directions simultaneously, introducing a combined horizontal and vertical misalignment. This combined shift simulates more complex overlay deviations that may occur in real-world scenarios, where misalignment in both directions can impact the layer alignment accuracy.

A critical metric between the surface contour and the underneath contour can be measured (212) following each virtual shift, giving rise to one or more measurements from the given image. The critical metric serves as a comprehensive measure of the relative positioning, distance, or area between the two layers, which could potentially impact the electrical yield and functional reliability of the chip. The term “critical metric” is used here to encompass various possible measurements/metrics, adapting to the specific needs of different chip designs and processing step requirements.

By way of example, the critical metric can represent any one of: a minimal distance between the contours, a minimal overlapped distance or area of the two contours, a minimal enclosure of distance or area of the two contours, and a distance from design to the contours, which can be critical for assessing the extent of layer alignment in certain applications. By way of example, the metric of minimal distance between the two contours measures the shortest distance between the boundaries of the surface contour and the underneath contour when there is no overlap between the two contours. It quantifies the closest point of approach between the two contours, providing an indicator of the degree of misalignment or separation between the layers. The metric of a minimal overlapped distance or area of the two contours refers to the smallest distance or area of overlap between the surface contour and the underneath contour when the two contours intersect. It measures the shortest distance across the overlapping region or the smallest shared area between the two contours. The metric of a minimal enclosure of distance or area of the two contours refers to the minimal non-overlapped distance or non-overlapped area between the two contours in cases where the contours are partially overlapped. Specifically, this metric quantifies the smallest distance or the smallest area where the two contours do not coincide or intersect. For instance, if the surface contour partially encloses the underneath contour, the minimal enclosure distance would represent the shortest path between a point on the boundary of the surface contour and a non-overlapping point on the boundary of the underneath contour. The metric of a distance from design to the contours measures the deviation of the surface contour or underneath contour from their respective design contours. For instance, for the surface contour, it indicates the distance from its actual boundary to the intended design boundary, reflecting process-induced variations in the surface layer. For the underneath contour, it measures the deviation from its designed position or shape.

The term “minimal” as used herein with respect to critical metrics, such as “minimal distance,” “minimal overlapped distance or area,” and “minimal enclosure of distance or area,” refers to the shortest or smallest value measured or calculated, but is not necessarily intended to imply an absolute minimum. Instead, “minimal” encompasses values that are relatively small within the context of the specific design and process conditions being evaluated. For instance, in some cases, even if the metric represents a relatively small value (e.g., small compared to a threshold or percentage), it still falls within the scope of protection and satisfies the intent of the present subject matter.

According to certain embodiments, in some cases, the critical metric may represent a distance (also referred to as a critical distance), such as, e.g., a minimal distance between the contours (in cases where the two contours are not overlapped), a minimal overlapped distance between the contours (in cases where the two contours are overlapped, as will be exemplified below with reference to FIG. 6), a minimal enclosure distance (e.g., the minimal non-overlapped distance between two contours in cases where the two contours are overlapped), or a distance from the design data of the contours to the respective contours. In some other cases, the metric might represent an area, such as the overlapped area between the two contours, an enclosure of an area (e.g., the non-overlapped area between two contours), etc. The specific critical metric to be measured can be selected based on the design requirements and the potential impact on chip performance. By calculating this metric for each shifted instance, the present disclosure can evaluate whether the POI features remain within specification limits across a range of overlay variations.

Once steps 208-212 have been performed for each image, a group of measurements can be obtained from the plurality of images, corresponding to the various POI occurrences across the FEM wafer. These measurements provide a detailed measurement dataset, capturing the effects of combined focus, exposure, and overlay variations on the critical dimensions and alignment of the POI. As described further below in relation to FIG. 4, these measurements can be then used to comprehensively evaluate the process window, enabling the qualification of focus, exposure, and overlay as a unified set of parameters for the process.

FIG. 4 illustrates a generalized flowchart of using the group of measurements for process window qualification in accordance with certain embodiments of the presently disclosed subject matter.

In block 402, the group of measurements can be compared with a predefined specification pertaining to the critical metric. This specification is often provided by the chip manufacturer, or derived based on the performance and reliability requirements of the chip design. The specification sets thresholds or limits for acceptable values of the critical metric, ensuring that the measurements meet the design's functional and operational standards. By way of example, if the critical metric represents a minimal overlapped distance, the specification would define the acceptable minimum value below which the electrical performance may be compromised. The comparison in 402 identifies the subset of measurements that fall within the specification limits (i.e., the measurements that meet the specification), effectively filtering out process conditions that fail to meet the required criteria.

Based on the subset of measurements that meet the specification, the margin and/or the center of a multi-dimensional process window characterized by focus, exposure, and overlay, can be determined (404). The margin represents the range or limits for each critical parameter (e.g., focus, exposure, and overlay) within which the chip design remains manufacturable while satisfying the specification. For instance, the focus margin indicates the upper and lower bounds of acceptable focus settings, the exposure margin defines the range of acceptable exposure doses, while the overlay margin specifies the allowable misalignments in X and/or Y directions. These margins help identify the process tolerance for each parameter, ensuring that even under slight variations within such margins in the manufacturing environment, the chip design can still be reliably produced. The center of the process window represents the optimal setting for focus, exposure, and overlay, where the critical metric is best aligned with the specification. This center provides a stable baseline for process control, minimizing variability and maximizing yield.

The determined margin and center of the process window have several practical applications in semiconductor manufacturing. Optionally, in some embodiments, the margin and/or the center of the multi-dimensional process window can be used (406) to adapt one or more critical parameters of a lithography tool or an etching tool, or remanufacture a mask used by the lithography tool with improved OPC on problematic POIs. By way of example, the margin and/or center can be used to calibrate the lithography/etching tool settings, ensuring that focus, exposure and overlay remain within the optimal range during production. By way of another example, if the process window margins indicate problematic POI regions (e.g., POIs with narrow tolerances or hotspots outside the specification), the mask can be remanufactured with improved OPC adjustments targeting these specific POIs. Enhanced OPC compensates for design sensitivities and process variations, broadening the process window and improving overall manufacturability.

Therefore, the margins and center of the process window can provide a reference for real-time monitoring and feedback control of the lithography and etching tools during mass production. By understanding the process window's limits, manufacturers can better predict yield variations under different process conditions, enabling more effective resource allocation and corrective actions to prevent yield loss.

In certain embodiments of the presently disclosed subject matter, overlay can be treated as a local parameter, specific to each location and pattern on the wafer. Unlike global parameters, overlay can vary significantly across different regions of the wafer due to factors such as intra-field variations, intra-die variations, and local pattern sensitivities. These local variations necessitate a more granular analysis to ensure accurate alignment of layers at every critical location.

For a given wafer, there may be hundreds of overlay parameters to be calibrated, each corresponding to a specific location of a POI within the wafer. For example, POIs located closer to the center of the die or the field (i.e., the field of the mask) may experience different overlay characteristics compared to those near the edges of the die or the field boundary, due to tool-induced distortions or substrate warping. These differences in overlay must be quantified and analyzed locally to understand their impact on the critical dimensions and alignment of patterns at each POI occurrence.

To address this, in some embodiments, the occurrences of the POI on each die can be associated with respective locations thereof within the die (and possibly also within the field), and the group of measurements obtained for the POI occurrences are thus also associated with the respective locations on the die (e.g., intra-die and intra-field). Each measurement reflects the critical metric (e.g., distance or area) under simulated overlay conditions that are locally relevant to the specific POI's position. By mapping these measurements to the spatial locations of the POIs, the present disclosure enables a location-specific process window qualification, wherein local overlay parameters are used to define margins and centers tailored to each POI location.

In such cases, the group of measurements can be compared with local specifications defined for the respective locations, and the margin and/or center of the process window can be determined as local parameters for the respective locations/regions, taking into account the specific overlay tolerances applicable to that region. This results in local process windows, which define the acceptable ranges of focus, exposure, and overlay for individual POIs, based on their unique spatial and design-related characteristics. By way of example, a POI at the center of a die might exhibit a wider overlay margin due to reduced intra-die distortions, whereas a POI near the edge of a die may have a narrower overlay margin due to higher sensitivity to misalignment. Similarly, POIs located near the field boundary might require tighter overlay control compared to those in the middle of the field, as field-edge effects can cause greater alignment variability.

In some cases, once local margins and centers are determined for each POI, these local parameters are then leveraged to adapt the process conditions for each location, maximizing the overall process window, while accounting for the unique characteristics of each POI and its position on the wafer. For instance, lithography tool parameters (e.g., overlay settings) can be optimized locally to minimize overlay variations at critical POI locations.

FIG. 6 illustrates a specific example of a Pattern of Interest (POI) and its behavior under variations in exposure, focus, and overlay, in accordance with certain embodiments of the present invention. The POI as exemplified comprises a surface layer having a surface structure 602 (whose contour is illustrated as an ellipse, thus is also referred to as ellipse 602) and an underneath layer having an underneath structure 604 (whose contour is illustrated as a circular contact, thus also referred to as contact 604).

FIG. 6 comprises three sub-illustrations: 600, 610, and 620, each depicting a scenario involving the surface structure 602 and the underneath structure 604 of the POI under varying process conditions.

In sub-illustration 600, the POI is depicted as it is designed, in the absence of any process variations. The two structures are perfectly aligned on their right boundaries, ensuring that the contact 604 is fully underneath the ellipse 602. This alignment guarantees proper electrical connection between the two layers. A critical distance 606 is defined as the minimal overlapped distance between the two structures in the horizontal (X) direction. This distance is measured to ensure that the overlap is sufficient for reliable electrical functionality. The illustration 600 represents the ideal baseline condition where the POI meets the design specifications, with no exposure, focus, or overlay variations affecting the alignment or dimensions of the structures.

Sub-illustration 610 represents a scenario where the surface structure 602 has undergone dimensional changes due to process variations such as exposure variation and/or focus variation. The underneath layer, as described above, is assumed to have been previously manufactured and remains unchanged as a fixed reference (as per the present disclosure). Therefore, the contact 604 retains its size and position, as shown in illustration 600. In this scenario, the ellipse 602 has shrunk in size due to process variations, simulating process conditions at a corner of a process window modulated by exposure and focus. The previously aligned right boundaries of the ellipse 602 and contact 604 now exhibit an offset, indicating that the two structures are no longer perfectly aligned. As a result, the critical distance 608, defined as the overlapped distance between the two structures in the horizontal (X) direction, has decreased compared to 606. This reduced overlap poses a potential risk to the electrical connection between the layers. This illustration 610 emphasizes how exposure and focus variations influence dimensional changes in the surface structure which can impact the critical overlap distance.

Sub-illustration 620 builds upon the scenario in 610 by introducing overlay variations to simulate potential misalignments that may occur during the manufacturing process. In this case, the ellipse 602 is virtually shifted to the left relative to the fixed contact 604, representing an overlay variation along the X direction. This additional shift exacerbates the misalignment between the two structures. The result is a further reduction in the critical distance 610, the overlapped distance in the horizontal (X) direction. In this example, the critical distance has likely been reduced below specification limits, jeopardizing the electrical connection between the layers.

In accordance with the present disclosure, the ellipse 602 can be virtually shifted multiple times, each time with a different overlay variation. These virtual shifts can occur in the X direction (horizontal), the Y direction (vertical), or a combination of both directions, simulating a range of potential overlay conditions. After each virtual shift, the critical distance 610 is measured to assess the impact of the overlay variation on the POI's functionality. This process generates a group of measurements that represent the critical distance 610 under varying process window conditions, defined by known exposure and focus variations (from 610) combined with the simulated overlay variations.

FIG. 6 demonstrates how the present disclosure allows for a comprehensive evaluation of the POI under combined exposure, focus, and overlay variations. The figure exemplifies, via 610, how process-induced changes (by exposure and focus variation) in the surface structure's dimensions affect critical alignment distances, and demonstrates, via 620, how to introduce virtual shifts to simulate additional overlay variations, enabling the evaluation of combined process window conditions. By systematically varying overlay conditions and measuring the resulting critical distance, it is possible to collect a dataset that reflects the POI's performance across the full spectrum of exposure, focus, and overlay variations.

This dataset serves as the foundation for defining a multi-dimensional process window (as described above with reference to FIG. 4), ensuring that the design specifications are met, even under complex real-world manufacturing conditions.

In accordance with the teachings of the present disclosure, the proposed methodology has been experimentally validated to demonstrate its feasibility and efficiency. By way of example, for a typical FEM wafer, an experimental process involves inspecting 100 POI locations on each die, with the wafer modulated for 10 focus variations and 10 exposure variations. This setup results in a total of 10,000 images being acquired across all POI occurrences on the wafer. These images are captured using a high-resolution metrology tool, such as a Critical Dimension Scanning Electron Microscope (CD-SEM), which provides the detailed imaging required for contour extraction and subsequent analysis.

To account for overlay variations, the proposed methodology introduces virtual shifts for each image. Specifically, in the experimental process, the contours of one layer (e.g., the fixed reference underneath layer) are virtually shifted relative to the other (e.g., the surface layer) to simulate 10 overlay variations in the X direction and 10 overlay variations in the Y direction, resulting in a comprehensive evaluation of misalignment scenarios. This experiment generates a total of 1 million critical distance measurements, corresponding to all combinations of focus, exposure, and overlay variations across the POI occurrences.

The efficiency of the proposed methodology is further supported by its system throughput. Using a metrology tool such as a CD-SEM, the experimental process requires approximately a couple of hours of tool time to acquire the 10,000 images and perform the associated virtual overlay shifts and measurements. This throughput demonstrates that the methodology is practical for real-world applications, as it achieves a balance between the granularity of data collected (1 million measurements) and the operational efficiency of the system.

By leveraging virtual overlay simulations alongside physical measurements for focus and exposure variations, the proposed methodology avoids the need for multiple wafers or extended tool times, while providing a comprehensive, multi-dimensional dataset. This dataset enables the precise qualification of the process window, encompassing focus, exposure, and overlay, while maintaining a reasonable operational efficiency compatible with production environments.

In some embodiments, in addition to the wafer being inspected by a metrology tool, such as a CD-SEM, according to the above teachings, the wafer can also undergo further inspection using an optical inspection tool to assess defectivity for each die. The optical inspection tool is capable of rapidly detecting defects, such as bridging, breaks, or pattern collapses, that may occur during the patterning process. This inspection provides a complementary dataset focused on identifying potential physical or structural defects across the wafer. By integrating the defectivity data with the group of measurements obtained from the CD-SEM (e.g., critical distances derived from focus, exposure, and overlay variations), a more holistic evaluation of the process window can be achieved.

This combination enables the simultaneous assessment of dimensional metrics (e.g., critical distances or areas) and defectivity metrics, offering insights into both quantitative measurements and qualitative defect trends. For example, while the metrology tool provides precise data on the alignment and dimensional accuracy of POIs, the optical inspection tool highlights zones with higher defect densities, helping to correlate defect-prone regions with variations in process parameters. Using this integrated approach, the process window for the chip design can be more comprehensively qualified, ensuring it accounts for both dimensional tolerances and defect control, thereby optimizing manufacturability and yield.

It is to be noted that examples illustrated in the present disclosure, such as, e.g., the exemplified surface and underneath structures, and the exemplified critical metrics, etc., are illustrated for exemplary purposes, and should not be regarded as limiting the present disclosure in any way. Other appropriate examples/implementations can be used in addition to, or in lieu of the above.

Among advantages of certain embodiments of the presently disclosed subject matter as described herein, is providing a methodology for qualifying a multi-dimensional process window encompassing focus, exposure, and overlay using a single wafer. By incorporating a hybrid approach that combines physical measurements for focus and exposure variations with virtual simulations for overlay variations, the present disclosure eliminates the need for multiple wafers or extensive physical experiments. This approach streamlines the qualification process, ensuring practical and efficient evaluation of critical parameters including overlay, while maintaining system throughput suitable for production environments.

Among further advantages of certain embodiments of the presently disclosed subject matter as described herein, is providing a possibility of localized process window qualification through the use of local overlay parameters specific to each POI location. Instead of treating overlay as a global parameter, certain embodiments of the present disclosure consider spatial and design-specific sensitivities, including intra-die and intra-field variations. This enables precise tailoring of process windows to the characteristics of individual POI locations, ensuring consistent performance and alignment across the entire wafer and contributing to a more robust global process window.

Among further advantages of certain embodiments of the presently disclosed subject matter is providing an integrated analysis framework that combines dimensional measurements with defectivity data obtained from optical inspection tools. By correlating critical metric measurements, such as distances or areas, with defectivity trends observed across the wafer, the present disclosure provides a holistic assessment of process robustness. This integration enhances the ability to identify defect-prone areas and align process refinements to address specific weaknesses, ultimately improving yield and reliability in semiconductor manufacturing.

Among further advantages of certain embodiments of the presently disclosed subject matter as described herein, is providing actionable data for optimizing process parameters and mask design. The present disclosure determines the margins and centers of the multi-dimensional process window for focus, exposure, and overlay, which can be used to adapt lithography tool settings, refine etching process parameters, and implement improved OPC strategies. These optimizations not only broaden the process window, but also enhance manufacturability, reducing defect risks and improving yield.

Among further advantages of certain embodiments of the presently disclosed subject matter as described herein, is providing a virtual overlay variation simulation system that leverages high-resolution see-through imaging with accurate contour extraction capabilities. By using secondary electron (SE) and backscattered electron (BSE) imaging, the present disclosure captures detailed, high-resolution images of the surface and underneath structures. Using precise contour extraction for both layers enables accurately delineating the boundaries and dimensions of the structures with high fidelity. This precise extraction capability ensures that the virtual overlay shifts simulate realistic alignment scenarios with minimal error, enabling efficient and accurate assessment of alignment variations across X and Y directions.

It is to be understood that the present disclosure is not limited in its application to the details set forth in the description contained herein or illustrated in the drawings.

In the present detailed description, numerous specific details are set forth in order to provide a thorough understanding of the disclosure. However, it will be understood by those skilled in the art that the presently disclosed subject matter may be practiced without these specific details. In other instances, well-known methods, procedures, components, and circuits have not been described in detail so as not to obscure the presently disclosed subject matter.

Unless specifically stated otherwise, as apparent from the present discussions, it is appreciated that throughout the specification discussions utilizing terms such as “obtaining”, “examining”, “qualifying”, “inspecting”, “providing”, “extracting”, “shifting”, “measuring”, “comparing”, “determining”, “using”, “adapting”, “characterizing”, or the like, refer to the action(s) and/or process(es) of a computer that manipulate and/or transform data into other data, said data represented as physical, such as electronic, quantities and/or said data representing the physical objects.

The terms “computer”, “computer-based system” or “computerized system” should be expansively construed to cover any kind of hardware-based electronic device with a data processing circuitry (e.g., digital signal processor (DSP), a graphics processing unit (GPU), a field programmable gate array (FPGA), including, by way of non-limiting example, the examination system, the process window qualification system, and respective parts thereof disclosed in the present application. The data processing circuitry (designated also as processing circuitry) can comprise, for example, one or more processors operatively connected to computer memory, loaded with executable instructions for executing operations, as further described below. The data processing circuitry encompasses a single processor or multiple processors, which may be located in the same geographical zone, or may, at least partially, be located in different zones, and may be able to communicate together.

The one or more processors referred to herein can represent one or more general-purpose processing devices such as a microprocessor, a central processing unit, or the like. More particularly, a given processor may be one of a complex instruction set computing (CISC) microprocessor, a reduced instruction set computing (RISC) microprocessor, a very long instruction word (VLIW) microprocessor, a processor implementing other instruction sets, or a processor implementing a combination of instruction sets. The one or more processors may also be one or more special-purpose processing devices such as an application specific integrated circuit (ASIC), a field programmable gate array (FPGA), a digital signal processor (DSP), a network processor, or the like. The one or more processors are configured to execute instructions for performing the operations and steps discussed herein.

The memories referred to herein can comprise one or more of the following: internal memory, such as, e.g., processor registers and cache, etc., main memory such as, e.g., read-only memory (ROM), flash memory, dynamic random access memory (DRAM) such as synchronous DRAM (SDRAM) or Rambus DRAM (RDRAM), etc.

The terms “non-transitory memory” and “non-transitory storage medium” used herein should be expansively construed to cover any volatile or non-volatile computer memory suitable to the presently disclosed subject matter. The terms should be taken to include a single medium or multiple media (e.g., a centralized or distributed database, and/or associated caches and servers) that store the one or more sets of instructions. The terms shall also be taken to include any medium that is capable of storing or encoding a set of instructions for execution by the computer and that cause the computer to perform any one or more of the methodologies of the present disclosure. The terms shall accordingly be taken to include, but not be limited to, a read only memory (“ROM”), random access memory (“RAM”), magnetic disk storage media, optical storage media, flash memory devices, etc.

The term “specimen” used in this specification should be expansively construed to cover any kind of physical objects or substrates including wafers, masks, reticles, and other structures, combinations and/or parts thereof used for manufacturing semiconductor integrated circuits, magnetic heads, flat panel displays, and other semiconductor-fabricated articles. A specimen is also referred to herein as a semiconductor specimen, and can be produced by manufacturing equipment executing corresponding manufacturing processes.

The term “examination” used in this specification should be expansively construed to cover any kind of operations related to defect detection, defect review, and/or defect classification of various types, segmentation, and/or metrology operations during and/or after the specimen fabrication process. Examination is provided by using non-destructive examination tools during or after manufacture of the specimen to be examined. By way of non-limiting example, the examination process can include runtime scanning (in a single or in multiple scans), imaging, sampling, detecting, reviewing, measuring, classifying, and/or other operations provided with regard to the specimen or parts thereof, using the same or different inspection tools. Likewise, examination can be provided prior to manufacture of the specimen to be examined, and can include, for example, generating an examination recipe(s) and/or other setup operations. It is noted that, unless specifically stated otherwise, the term “examination”, or its derivatives used in this specification, is not limited with respect to resolution or size of an inspection area. A variety of non-destructive examination tools includes, by way of non-limiting example, scanning electron microscopes (SEM), atomic force microscopes (AFM), optical inspection tools, etc.

The term “metrology operation” used in this specification should be expansively construed to cover any metrology operation procedure used to extract metrology information relating to one or more structural elements on a semiconductor specimen. In some embodiments, the metrology operations can include measurement operations, such as, e.g., critical dimension (CD) measurements performed with respect to certain structural elements on the specimen, including but not limiting to the following: dimensions (e.g., line widths, line spacing, contact diameters, size of the element, edge roughness, gray level statistics, etc.), shapes of elements, distances within or between elements, related angles, overlay information associated with elements corresponding to different design levels, etc. Measurement results such as measured images are analyzed, for example, by employing image-processing techniques. Note that, unless specifically stated otherwise, the term “metrology”, or derivatives thereof used in this specification, is not limited with respect to measurement technology, measurement resolution, or size of inspection area.

The term “defect” used in this specification should be expansively construed to cover any kind of abnormality or undesirable feature/functionality formed on a specimen. In some cases, a defect may be a defect of interest (DOI) which is a real defect that has certain effects on the functionality of the fabricated device, thus is in the customer's interest to be detected. For instance, any “killer” defects that may cause yield loss can be indicated as a DOI. In some other cases, a defect may be a nuisance (also referred to as “false alarm” defect) which can be disregarded because it has no effect on the functionality of the completed device and does not impact yield.

The term “defect candidate” used in this specification should be expansively construed to cover a suspected defect location on the specimen which is detected to have relatively high probability of being a defect of interest (DOI). Therefore, a DOI candidate, upon being reviewed/tested, may actually be a DOI, or, in some other cases, it may be nuisances, or random noise that can be caused by different variations (e.g., process variation, color variation, mechanical and electrical variations, etc.) during inspection.

The term “design data” used in the specification should be expansively construed to cover any data indicative of hierarchical physical design (layout) of a specimen. Design data can be provided by a respective designer and/or can be derived from the physical design (e.g., through complex simulation, simple geometric and Boolean operations, etc.). Design data can be provided in different formats as, by way of non-limiting examples, GDSII format, OASIS format, etc. Design data can be presented in vector format, grayscale intensity image format, or otherwise.

The term “image(s)” or “image data” used in the specification should be expansively construed to cover any original images/frames of the specimen captured by an examination tool during the fabrication process, derivatives of the captured images/frames obtained by various pre-processing stages, and/or computer-generated synthetic images (in some cases based on design data). Depending on the specific way of scanning (e.g., one-dimensional scan such as line scanning, two-dimensional scan in both x and y directions, or dot scanning at specific spots, etc.), image data can be represented in different formats, such as, e.g., as a gray level profile, a two-dimensional image, or discrete pixels, etc. It is to be noted that in some cases the image data referred to herein can include, in addition to images (e.g., captured images, processed images, etc.), numeric data associated with the images (e.g., metadata, hand-crafted attributes, etc.). It is further noted that images or image data can include data related to a processing step/layer of interest, or a plurality of processing steps/layers of a specimen.

It is appreciated that, unless specifically stated otherwise, certain features of the presently disclosed subject matter, which are described in the context of separate embodiments, can also be provided in combination in a single embodiment. Conversely, various features of the presently disclosed subject matter, which are described in the context of a single embodiment, can also be provided separately or in any suitable sub-combination. In the present detailed description, numerous specific details are set forth in order to provide a thorough understanding of the methods and apparatus.

It will also be understood that the system according to the present disclosure may be, at least partly, implemented on a suitably programmed computer. Likewise, the present disclosure contemplates a computer program being readable by a computer for executing the method of the present disclosure. The present disclosure further contemplates a non-transitory computer-readable memory tangibly embodying a program of instructions executable by the computer for executing the method of the present disclosure.

The present disclosure is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based may readily be utilized as a basis for designing other structures, methods, and systems for carrying out the several purposes of the presently disclosed subject matter.

Those skilled in the art will readily appreciate that various modifications and changes can be applied to the embodiments of the present disclosure as hereinbefore described without departing from its scope, defined in and by the appended claims.

1. A computerized system of process window qualification, the system comprising a processing circuitry configured to:
obtain a wafer comprising a plurality of dies respectively printed under a plurality of process window conditions characterized by varying values of focus and exposure, wherein the wafer is fabricated in accordance with a chip design containing a pattern of interest (POI), resulting in one or more occurrences of the POI on each die, the POI comprising at least a surface structure and an underneath structure;
inspect the wafer at locations corresponding to the occurrences of the POI on each die, to obtain a plurality of images each capturing an occurrence of the POI on the wafer; and
provide a group of measurements pertaining to the POI from the plurality of images, comprising, for each given image:
extract a surface contour of the surface structure and an underneath contour of the underneath structure;
shift one of the surface contour and underneath contour relative to the other contour one or more times to simulate one or more overlay variations; and
measure a critical metric between the surface contour and the underneath contour following each shift, giving rise to one or more measurements from the given image.

2. The computerized system according to claim 1, wherein the processing circuitry is further configured to:
compare the group of measurements with a specification pertaining to the critical metric; and
determine at least one of a margin and a center of a multi-dimensional process window characterized by focus, exposure, and overlay, based on a subset of measurements that meet the specification.

3. The computerized system according to claim 2, wherein the at least one of a margin and a center of the multi-dimensional process window is usable to adapt one or more critical parameters of at least one of a lithography tool and an etching tool, or remanufacture a mask used by the lithography tool with improved Optical Proximity Correction (OPC) on problematic POIs.

4. The computerized system according to claim 1, wherein the locations corresponding to the occurrences of the POI are provided by Optical Proximity Correction (OPC) simulation.

5. The computerized system according to claim 1, wherein the critical metric represents one of: a minimal distance between the surface contour and the underneath contour, a minimal overlapped distance or area of the surface contour and the underneath contour, a minimal enclosure of distance or area of the surface contour and the underneath contour, and a distance from design to at least one of the surface contour and the underneath contour.

6. The computerized system according to claim 1, wherein the shifting is to simulate one or more overlay variations in at least one of an X direction and a Y direction.

7. The computerized system according to claim 2, wherein the occurrences of the POI on each die are associated with respective locations thereof within the die, and the group of measurements are provided with respect to the respective locations associated with the occurrences and compared with local specifications defined for the respective locations, and wherein the at least one of a margin and a center is determined as a local parameter for the respective locations, enabling to derive local process windows respectively for the occurrences of the POI.

8. The computerized system according to claim 1, wherein the surface structure is from a surface layer of the wafer which is printed under the plurality of process window conditions, while the underneath structure is from an underneath layer of the wafer which is printed under a fixed process window condition.

9. The computerized system according to claim 1, wherein the wafer is inspected using an e-beam tool to obtain the plurality of images, each image comprising a secondary electron (SE) image component from which the surface contour is extracted, and a back-scattered electron (BSE) image component from which the underneath contour is extracted.

10. The computerized system according to claim 1, wherein the wafer is further inspected using an optical inspection tool to assess defectivity for each die, wherein the assessed defectivity and the group of measurements are used in combination for qualifying the process window for the chip design.

11. A computerized method of process window qualification, the method comprising:
obtaining a wafer comprising a plurality of dies respectively printed under a plurality of process window conditions characterized by varying values of focus and exposure, wherein the wafer is fabricated in accordance with a chip design containing a pattern of interest (POI), resulting in one or more occurrences of the POI on each die, the POI comprising at least a surface structure and an underneath structure;
inspecting the wafer at locations corresponding to the occurrences of the POI on each die, to obtain a plurality of images each capturing an occurrence of the POI on the wafer; and
providing a group of measurements pertaining to the POI from the plurality of images, comprising, for each given image:
extracting a surface contour of the surface structure and an underneath contour of the underneath structure;
shifting one of the surface contour and underneath contour relative to the other contour one or more times to simulate one or more overlay variations; and
measuring a critical metric between the surface contour and the underneath contour following each shift, giving rise to one or more measurements from the given image.

12. The computerized method according to claim 11, further comprising:
comparing the group of measurements with a specification pertaining to the critical metric; and
determining at least one of a margin and a center of a multi-dimensional process window characterized by focus, exposure, and overlay, based on a subset of measurements that meet the specification.

13. The computerized method according to claim 12, wherein the at least one of a margin and a center of the multi-dimensional process window is usable to adapt one or more critical parameters of at least one of a lithography tool and an etching tool, or remanufacture a mask used by the lithography tool with improved Optical Proximity Correction (OPC) on problematic POIs.

14. The computerized method according to claim 11, wherein the locations corresponding to the occurrences of the POI are provided by Optical Proximity Correction (OPC) simulation.

15. The computerized method according to claim 11, wherein the critical metric represents one of: a minimal distance between the surface contour and the underneath contour, a minimal overlapped distance or area of the surface contour and the underneath contour, a minimal enclosure of distance or area of the surface contour and the underneath contour, and a distance from design to at least one of the surface contour and the underneath contour.

16. The computerized method according to claim 11, wherein the shifting is to simulate one or more overlay variations in at least one of an X direction and a Y direction.

17. The computerized method according to claim 12, wherein the occurrences of the POI on each die are associated with respective locations thereof within the die, and the group of measurements are provided with respect to the respective locations associated with the occurrences and compared with local specifications defined for the respective locations, and wherein the at least one of a margin and a center is determined as a local parameter for the respective locations, enabling to derive local process windows respectively for the occurrences of the POI.

18. The computerized method according to claim 11, wherein the surface structure is from a surface layer of the wafer which is printed under the plurality of process window conditions, while the underneath structure is from an underneath layer of the wafer which is printed under a fixed process window condition.

19. The computerized method according to claim 11, wherein the wafer is further inspected using an optical inspection tool to assess defectivity for each die, wherein the assessed defectivity and the group of measurements are used in combination for qualifying the process window for the chip design.

20. A non-transitory computer readable storage medium tangibly embodying a program of instructions that, when executed by a computer, cause the computer to perform a method of process window qualification, the method comprising:
obtaining a wafer comprising a plurality of dies respectively printed under a plurality of process window conditions characterized by varying values of focus and exposure, wherein the wafer is fabricated in accordance with a chip design containing a pattern of interest (POI), resulting in one or more occurrences of the POI on each die, the POI comprising at least a surface structure and an underneath structure;
inspecting the wafer at locations corresponding to the occurrences of the POI on each die, to obtain a plurality of images each capturing an occurrence of the POI on the wafer; and
providing a group of measurements pertaining to the POI from the plurality of images, comprising, for each given image:
extracting a surface contour of the surface structure and an underneath contour of the underneath structure;
shifting one of the surface contour and underneath contour relative to the other contour one or more times to simulate one or more overlay variations; and
measuring a critical metric between the surface contour and the underneath contour following each shift, giving rise to one or more measurements from the given image.
